(19) United States
(12) Patent Application Publication
(10) Pub. No.: US 2015/0009446 A1
(43) Pub. Date: Jan. 8, 2015

(54) LCD PANEL AND A METHOD OF MANUFACTURING THE SAME

(71) Applicants: Jiali Jiang, Shenzhen (CN); Peng Du, Shenzhen (CN); Shihchyn Lin, Shenzhen (CN)

(72) Inventors: Jiali Jiang, Shenzhen (CN); Peng Du, Shenzhen (CN); Shihchyn Lin, Shenzhen (CN)

(73) Assignee: Shenzhen China Star Optoelectronics Technology Co., Ltd., Shenzhen (CN)

(21) Appl. No.: 13/502,744

(22) PCT Filed: Mar. 27, 2012
(86) PCT No.: PCT/CN2012/073091

§ 371 Date: Apr. 19, 2012

(30) Foreign Application Priority Data
Mar. 26, 2012 (CN) 201210081847.8

(51) Int. Cl. G02F 1/1362; H01L 21/283; H01L 21/768; G02F 1/1368; H01L 27/12

(52) U.S. Cl. CPC G02F 1/136213; G02F 1/1368; G02F 1/13624; G02F 1/136286; G02F 1/136227; H01L 27/1255; H01L 27/1259; H01L 21/76802; H01L 21/283; H01L 27/124; G02F 2001/13629
USPC 349/48; 438/158

(57) ABSTRACT

A liquid crystal display panel and a method of manufacturing the same are proposed. A bottom electrode of an electrode used as a storage capacitor is disposed between a scan line and a voltage controlling line. A first conducting area and a second conducting area of another electrode used as the storage capacitor are formed by a transparent conducting layer. Because the storage capacitor is formed between the scan line and the voltage controlling line, a second sub-pixel electrode has larger layout space. The aperture ratio of the second sub-pixel electrode is increased accordingly.

### BACKGROUND OF THE INVENTION

1. Field of the Invention.

The present invention relates to a liquid crystal display (LCD) panel and a method of manufacturing the same, and more particularly, to an LCD panel capable of increasing the aperture ratio of a pixel without a decrease in storage capacitance and a method of manufacturing the same.

2. Description of the Prior Art

An advanced monitor with multiple functions is an important feature for use in current consumer electronic products. Liquid crystal displays (LCDs) which are colorful monitors with high resolution are widely used in various electronic products such as monitors for mobile phones, personal digital assistants (PDAs), digital cameras, laptop computers, and notebook computers.

Transistor liquid crystal display has advantages in that it provides higher image quality, minimizes the use of the space, consumes less power, emits no radiation, and so on, so the transistor liquid crystal display has become the mainstream product of the market stage by stage. Further, a high contrast ratio, a fast response time, and wide viewing angles are desired aspects of any liquid crystal display (LCD) at present.

When a user views images from an LCD panel at a large viewing angle, the user may find the images to be distorted. This is because colors shown on the images deviate from the original colors which should be shown. In order to inhibit color washout, various pixel structures have been developed. Referring to FIG. 1, FIG. 1 is a design diagram showing a conventional pixel 10 capable of inhibiting color washout. The pixel 10 comprises two sub-pixel electrodes 11 and 12. A storage capacitor 17 in the pixel 10 is disposed between the sub-pixel electrode 12 and a voltage controlling line 16. However, the aperture rate of the sub-pixel electrode 12 in such a design is affected.

### SUMMARY OF THE INVENTION

It is therefore an object of the present invention to provide an LCD panel and a method of manufacturing the same. A storage capacitor is disposed between a scan line and a voltage controlling line so as to increase the aperture ratio of a pixel. In this way, problems occurring in the conventional technology will be solved.

According to the present invention, a liquid crystal display (LCD) panel comprises a glass substrate; a scan line, formed by a first metallic layer and disposed on the glass substrate, for transmitting a scan signal; a voltage controlling line, formed by the first metallic layer and disposed on the glass substrate, for transmitting a control signal; an insulating layer, disposed on the scan line and the voltage controlling line; a data line, formed by a second metallic layer and disposed on the insulating layer, for transmitting a data signal; a first sub-pixel electrode and a second sub-pixel electrode comprising a first conducting area, formed by a transparent conducting layer; a first transistor, electrically connected to the first sub-pixel electrode; a second transistor, electrically connected to the voltage controlling line and the first transistor; a common electrode, formed by the first metallic layer and disposed on the glass substrate, for transmitting a common signal; a second conducting area, formed by the transparent conducting layer and electrically connected to the common electrode; a bottom electrode formed by the second metallic layer, disposed on the insulating layer from a side view and from a top view located between the scan line and the voltage controlling line, and electrically connected to the second transistor; a first storage capacitor formed by the bottom electrode and the first conducting area of the second sub-pixel electrode; and a second capacitor formed by the bottom electrode and the second conducting area.

In one aspect of the present invention, the LCD panel further comprises a passivation layer, disposed on the second metallic layer; a first via through the passivation layer, disposed between the scan line and the voltage controlling line from the top view so that the first sub-pixel electrode is electrically connected to the first transistor through the first via; and a second via through the passivation layer and the insulating layer, disposed between the voltage controlling line and the second sub-pixel electrode from the top view so that the common electrode is electrically connected to the second conducting area through the second via.

In another aspect of the present invention, a projection of the first storage capacitor and a projection of the second storage capacitor onto the glass substrate are between a projection of the scan line and a projection of the voltage controlling line onto the glass substrate.

In still another aspect of the present invention, the transparent conducting layer is made of indium tin oxide (ITO).

In yet another aspect of the present invention, the first transistor, the second transistor, the scan line, and the voltage controlling line are disposed between the first sub-pixel electrode and the second sub-pixel electrode from the top view.

According to the present invention, a method of manufacturing an LCD panel comprises the steps of: providing a glass substrate; forming a first metallic layer on the glass substrate; etching the first metallic layer to form a gate of a TFT, a voltage controlling line, a common line and a scan line; forming an insulating layer on the gate of the TFT, the voltage controlling line, the common line, and the scan line; forming a second metallic layer and etching the second metallic layer to form a source and a drain of the TFT, a data line and a bottom electrode which is between the voltage controlling line and the scan line from a top view; forming a passivation layer on the second metallic layer; etching the passivation layer to form a first via and a second via; and forming a transparent conducting layer and etching the transparent conducting layer to form a first sub-pixel electrode, a second sub-pixel electrode, and a second conducting area, wherein the first sub-pixel electrode is electrically connected to the TFT through the first via; the common line is electrically connected to the second conducting area through the second via; a first storage capacitor is formed by the bottom electrode and the first conducting area of the second sub-pixel electrode; and a second storage capacitor is formed by the bottom electrode and the second conducting area.

In one aspect of the present invention, a projection of the first storage capacitor and a projection of the second storage capacitor onto the glass substrate are between a projection of the scan line and a projection of the voltage controlling line onto the glass substrate.

In another aspect of the present invention, the transparent conducting layer is made of indium tin oxide (ITO).

In still another aspect of the present invention, the first transistor, the second transistor, the scan line, and the voltage controlling line are disposed between the first sub-pixel electrode and the second sub-pixel electrode.

In contrast to the conventional technology, a bottom electrode of an electrode used as the storage capacitor is disposed between a scan line and a voltage controlling line, and a first conducting area and a second conducting area of another electrode used as the storage capacitor are formed by a transparent conducting layer in the present invention. Because the storage capacitor is formed between the scan line and the voltage controlling line, a second sub-pixel electrode has larger layout space. The aperture ratio of the second sub-pixel electrode is increased accordingly.

These and other features, aspects and advantages of the present disclosure will become understood with reference to the following description, appended claims and accompanying figures.

### BRIEF DESCRIPTION OF THE DRAWINGS

FIG. 1 is a design diagram showing a conventional pixel capable of inhibiting color washout.

FIG. 2 shows a schematic diagram of an LCD panel according to a preferred embodiment of the present invention.

FIG. 3 is a partial enlargement diagram of region B shown in FIG. 2.

FIGS. 4 to 7 show schematic diagrams of forming the LCD panel.

### DETAILED DESCRIPTION OF THE PREFERRED EMBODIMENTS

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

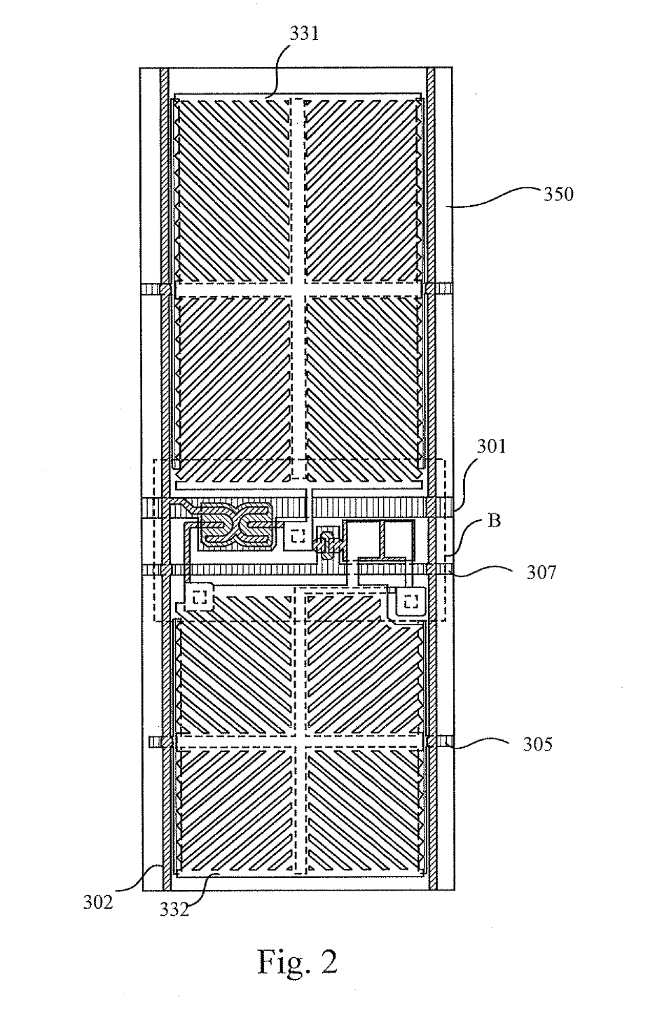

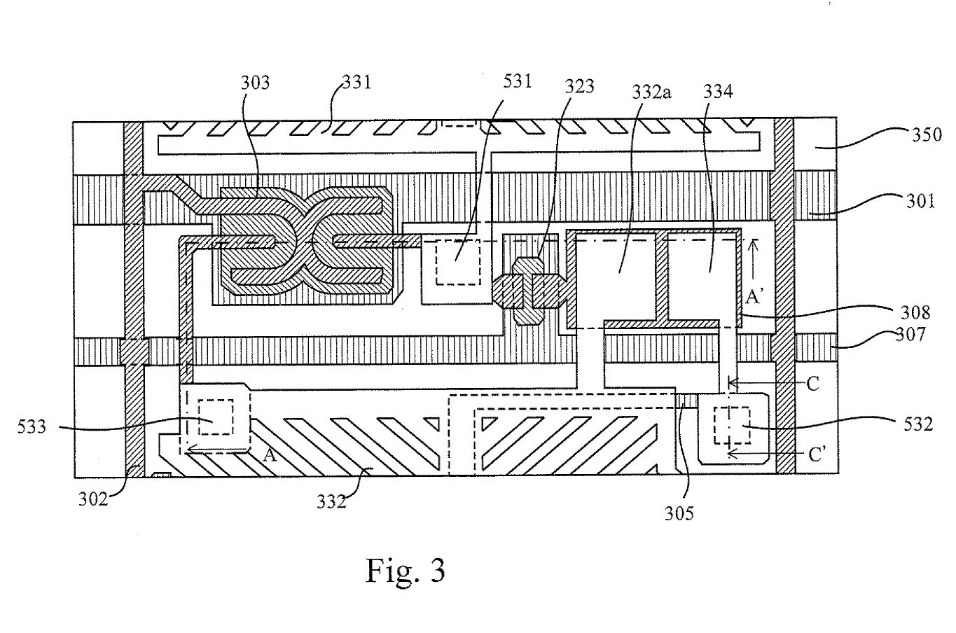

Referring to FIG. 2 and FIG. 3, FIG. 2 shows a schematic diagram of an LCD panel 300 according to a preferred embodiment of the present invention. FIG. 3 is a partial enlargement diagram of region B shown in FIG. 2. The LCD panel 300 comprises a plurality of data lines, a plurality of scan lines, a plurality of voltage controlling lines, a plurality of transistors, and a plurality of pixel units. Each of the pixel units comprises transistors 303 and 323, a first sub-pixel electrode 331, and a second sub-pixel electrode 332. To have a better understanding of the diagrams of the embodiment, only a data line 302, a scan line 301, a common voltage line 305, and a voltage controlling line 307 are shown in the embodiment. A gate 371 of the first transistor 303 is coupled to the scan line 301. A source 373 of the first transistor 303 is coupled to the data line 302. A gate of the second transistor 323 is coupled to the voltage controlling line 307. A source of the second transistor 323 is coupled to a drain 374 of the first transistor 303. A drain of the second transistor 323 is coupled to a bottom electrode 308. Moreover, the drain 374 of the first transistor 303 is coupled to the first and second sub-pixel electrodes 331 and 332. The voltage controlling line 307 is used for providing a control signal.

A method of driving the LCD panel 300 is as follows: A scan signal output by a gate driver (not shown) is transmitted to a plurality of first transistors 303 through the scan line 301, and the plurality of first transistors 303 connected to the scan line 301 are turned on in order. Meanwhile, a corresponding data signal is output by a source driver (not shown) and transmitted to the plurality of first transistors 303 through the data line 302. Then, the data signal passes through the plurality of first transistors 303 and is transmitted to the first and second sub-pixel electrodes 331 and 332 so that each of the components obtains its required voltage at full charge. LCs on the first and second sub-pixel electrodes 331 and 332 twist based on a difference in voltage of the data signal and a difference in voltage of common voltage of the common voltage line 305. Consequently, the first and second sub-pixel electrodes 331 and 332 show various grayscales. The gate driver outputs the scan signal row by row through the plurality of scan lines to turn on the plurality of first transistors 303 in each row. Then, the source driver charges/discharges the first and second sub-pixel electrodes 331 and 332 in each row. According to this sequence, an image will be completely shown on the LCD panel 300.

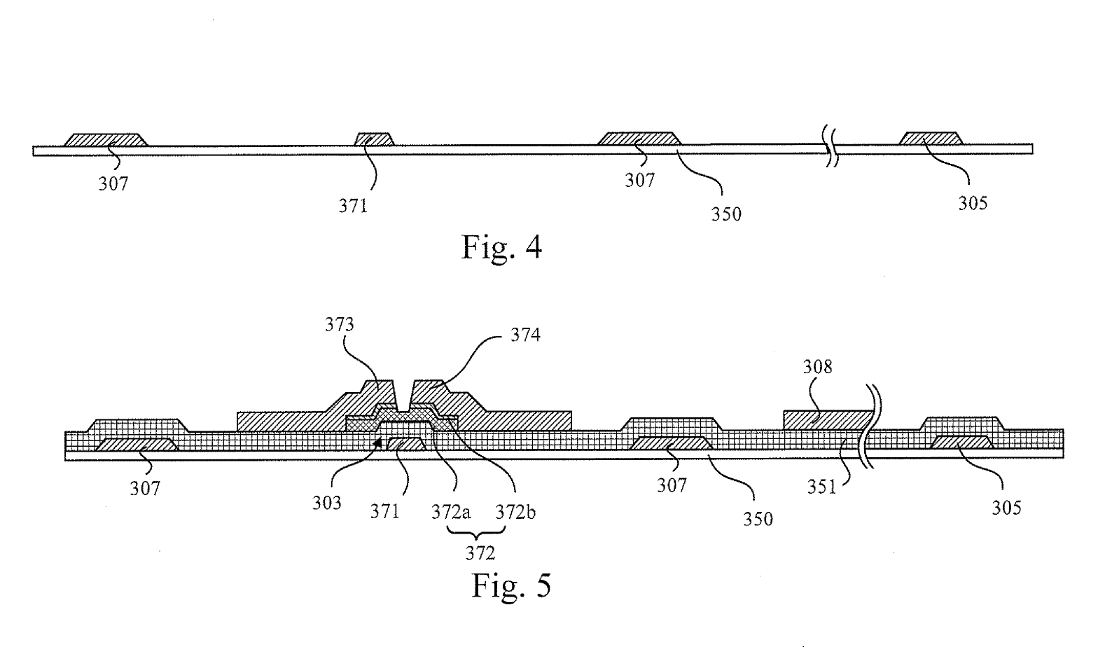

A manufacturing process of the LCD panel 300 panel is disclosed as follows. Referring to FIGS. 4 to 7, FIGS. 4 to 7 show schematic diagrams of forming the flat display panel 300. FIGS. 4 to 7 are also cross section views of the flat display panel 300 taken along lines A-A′ and C-C′ of FIG. 3.

Referring to FIG. 4, on the beginning a glass substrate 350 serves as a bottom substrate. Next, a metallic thin-film deposition is conducted on the glass substrate 350 to form a first metallic layer (not shown) on the surface of the glass substrate 350. Also, a first photo etching process (PEP) is conducted using a first mask to etch the gate 371 of the first transistor 303, the common voltage line 305, the voltage controlling line 307, and the scan line 311. The scan line 301 is not marked in FIG. 4, but it will be appreciated by those skilled in the art that the gate 371 is practically part of the scan line 301.

Referring to FIG. 3 and FIG. 5, an insulating layer 351 made of silicon nitride (SiNx) is deposited and covers the gate 371, the common voltage line 305, the voltage controlling line 307, and the scan line 301. An amorphous Si (a-Si) layer and an N+ a-Si layer at high electron doping concentrations are successively deposited on the insulating layer 351. Next, a second metallic layer (not shown) covers the a-Si layer and the N+a-Si layer at high electron doping concentrations. Next, a semiconductor layer 372 is formed after the a-Si layer and the N+ a-Si layer are etched using a second mask. Meanwhile, the second metallic layer is etched to form the source 373, the drain 374, the bottom electrode 308, and the data line 302. The semiconductor layer 372 comprises an a-Si layer 372a and an ohmic contact layer 372b. The a-Si layer 372a serves as a passage of the first transistor 303. The ohmic contact layer 372b is used for reducing resistance. The data line 302 is not marked in FIG. 5, but it will be appreciated by those skilled in the art that the source 373 is practically part of the data line 302.

In addition, the a-Si layer, the N+a-Si layer, and the second metallic layer are etched using the second mask at the same time in the present embodiment. The structure is shown in FIG. 5. However, different steps are adopted in another embodiment. Firstly, the a-Si layer and the N+a-Si layer are formed on the insulating layer 351. Next, the a-Si layer and the N+a-Si layer are etched using the second mask to form the semiconductor layer 372. Next, the second metallic layer is formed on the semiconductor layer 372 and the insulating layer 351. Finally, the second metallic layer is etched using another mask to form the source 373, the drain 374, and the data line 302.

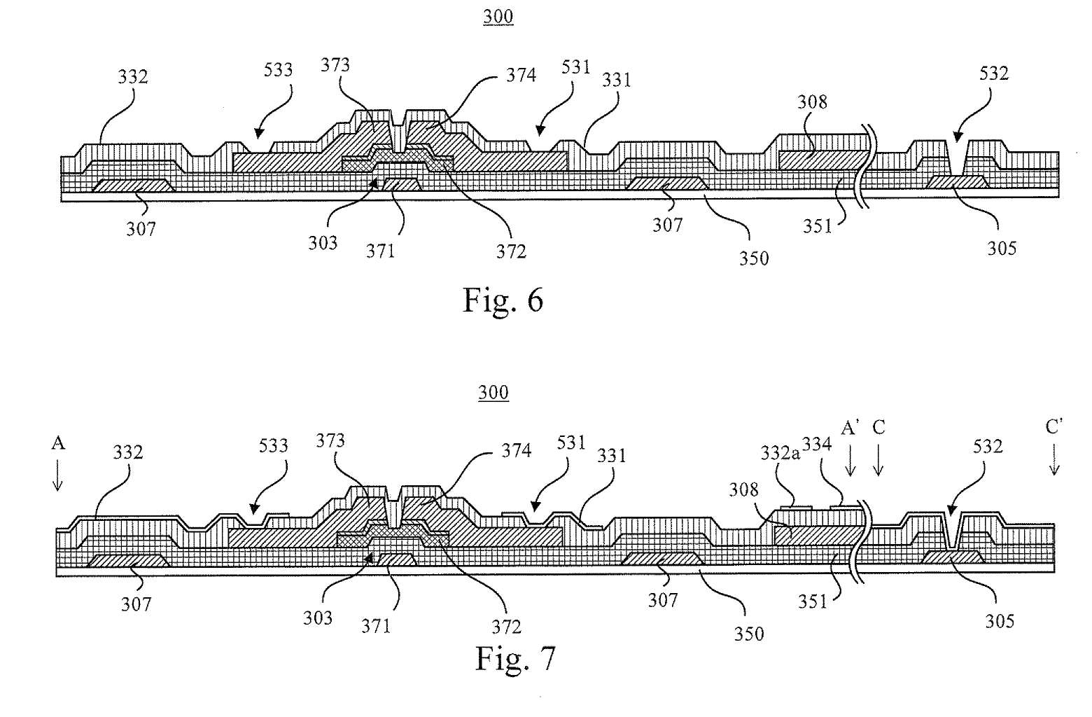

Referring to FIG. 3 and FIG. 6, a passivation layer 375 made of SiNx is deposited. Next, a third PEP is conducted using a third mask to remove part of the passivation layer 375 on the drain 374 until the surface of the drain'374 is exposed for forming a first via 531, a second via 532 and a third via 533. A projection of the first via 531 onto the glass substrate 350 is between a projection of the scan line 301 and a projection of the voltage controlling line 307 onto the glass substrate 350. The second via 532, disposed between the voltage controlling line 307 and the second sub-pixel electrode 332, traverses the passivation layer 375 and the insulating layer 351. The second transistor 323 is not shown in FIGS. 4 to 6, but it will be appreciated by those skilled in the art that the formation order of the second transistor 323 is identical to that of the first transistor 303. No further details will be provided hereafter.

Referring to FIG. 3 and FIG. 7, FIG. 7 is a cross section view of the flat display panel 300 taken along lines A-A′ and C-C′ of FIG. 3. A transparent conducting layer made of indium tin oxide (ITO) is formed on the passivation layer 375. Next, the first sub-pixel electrode 331, the second sub-pixel electrode 332, and a second conducting area 334 are formed after the transparent conducting layer is etched using a fourth mask. The first sub-pixel electrode 331 is electrically connected to the drain 374 of the first transistor 303 through the first via 531. The second sub-pixel electrode 332 is electrically connected to the drain 374 through the third via 533. The common electrode 305 is electrically connected to the second conducting area 334 through the second via 532. The second sub-pixel electrode 332 comprises a first conducting area 332a which traverses a signal controlling line 306. Both of the first conducting area 332a and the second conducting area 334 are disposed on the bottom electrode 308. Therefore, a first storage capacitor Cs1 is formed by the first conducting area 332a of the second sub-pixel electrode 332 and the bottom electrode 308. A second storage capacitor Cs2 is formed by the second conducting area 334 and the bottom electrode 308.

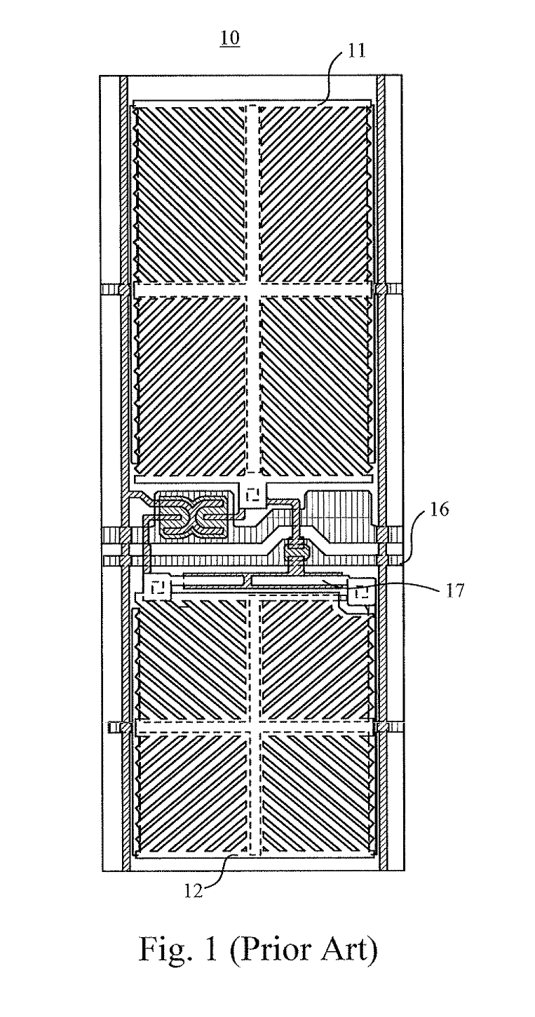

Referring to FIG. 2, the first storage capacitors Cs1 formed by the bottom electrode 308 and the first conducting area 332a of the second sub-pixel electrode 332, and the second storage capacitors Cs2 formed by the bottom electrode 308 and the second conducting area 334 are disposed between the scan line 301 and the voltage controlling line 306. Therefore, the second sub-pixel electrode 332 has larger layout space. Compared with the conventional technology as shown in FIG. 1, the aperture ratio of the second sub-pixel electrode 332 is increased to 69.9% from 67.17% in the present invention.

While the present invention has been described in connection with what is considered the most practical and preferred embodiments, it is understood that this invention is not limited to the disclosed embodiments but is intended to cover various arrangements made without departing from the scope of the broadest interpretation of the appended claims.

What is claimed is:

1. A liquid crystal display (LCD) panel, comprising:
a glass substrate;
a scan line, formed by a first metallic layer and disposed on the glass substrate, for transmitting a scan signal;
a voltage controlling line, formed by the first metallic layer and disposed on the glass substrate, for transmitting a control signal;
an insulating layer, disposed on the scan line and the voltage controlling line;
a data line, formed by a second metallic layer and disposed on the insulating layer, for transmitting a data signal;
a first sub-pixel electrode and a second sub-pixel electrode comprising a first conducting area, formed by a transparent conducting layer;
a first transistor, electrically connected to the first sub-pixel electrode;
a second transistor, electrically connected to the voltage controlling line and the first transistor;
a common electrode, formed by the first metallic layer and disposed on the glass substrate, for transmitting a common signal; a second conducting area, formed by the transparent conducting layer and electrically connected to the common electrode;
a bottom electrode formed by the second metallic layer, disposed on the insulating layer from a side view and from a top view located between the scan line and the voltage controlling line, and electrically connected to the second transistor;
a first storage capacitor formed by the bottom electrode and the first conducting area of the second sub-pixel electrode; and
a second capacitor formed by the bottom electrode and the second conducting area.

2. The LCD panel as claimed in claim 1 further comprising:
a passivation layer, disposed on the second metallic layer;
a first via through the passivation layer, disposed between the scan line and the voltage controlling line from the top view so that the first sub-pixel electrode is electrically connected to the first transistor through the first via; and
a second via through the passivation layer and the insulating layer, disposed between the voltage controlling line and the second sub-pixel electrode from the top view so that the common electrode is electrically connected to the second conducting area through the second via.

3. The LCD panel as claimed in claim 2, wherein a projection of the first storage capacitor and a projection of the second storage capacitor onto the glass substrate are between a projection of the scan line and a projection of the voltage controlling line onto the glass substrate.

4. The LCD panel as claimed in claim 1, wherein the transparent conducting layer is made of indium tin oxide (ITO).

5. The LCD panel as claimed in claim 1, wherein the first transistor, the second transistor, the scan line, and the voltage controlling line are disposed between the first sub-pixel electrode and the second sub-pixel electrode from the top view.

6. A method of manufacturing an LCD panel, comprising:
providing a glass substrate;
forming a first metallic layer on the glass substrate;
etching the first metallic layer to form a gate of a TFT, a voltage controlling line, a common line and a scan line;
forming an insulating layer on the gate of the TFT, the voltage controlling line, the common line, and the scan line;
forming a second metallic layer and etching the second metallic layer to fowl a source and a drain of the TFT, a data line and a bottom electrode which is between the voltage controlling line and the scan line from a top view;
forming a passivation layer on the second metallic layer;
etching the passivation layer to form a first via and a second via; and
forming a transparent conducting layer and etching the transparent conducting layer to form a first sub-pixel electrode, a second sub-pixel electrode, and a second conducting area, wherein the first sub-pixel electrode is electrically connected to the TFT through the first via;
the common line is electrically connected to the second conducting area through the second via; a first storage capacitor is formed by the bottom electrode and the first conducting area of the second sub-pixel electrode; and a second storage capacitor is formed by the bottom electrode and the second conducting area.

7. The method as claimed in claim 6, wherein a projection of the first storage capacitor and a projection of the second storage capacitor onto the glass substrate are between a projection of the scan line and a projection of the voltage controlling line onto the glass substrate.

8. The method as claimed in claim 6, wherein the transparent conducting layer is made of indium tin oxide (ITO).

9. The method as claimed in claim 6, wherein the first transistor, the second transistor, the scan line, and the voltage controlling line are disposed between the first sub-pixel electrode and the second sub-pixel electrode.
